(19) United States
(12) Patent Application Publication
(10) Pub. No.: US 2017/0243739 A1
(43) Pub. Date: Aug. 24, 2017

(54) 3D MICROMOLD AND PATTERN TRANSFER

(71) Applicant: SKYWORKS SOLUTIONS, INC., Woburn, MA (US)

(72) Inventors: Bradley Paul Barber, Acton, MA (US); Kezia Cheng, Lowell, MA (US)

(21) Appl. No.: 15/440,223

(22) Filed: Feb. 23, 2017

Related U.S. Application Data
(60) Provisional application No. 62/299,129, filed on Feb. 24, 2016.

(51) Int. Cl. H01L 21/027; H01L 21/52; H01L 25/00; H01L 23/00

(52) U.S. Cl. CPC H01L 21/0274; H01L 24/83; H01L 21/52; H01L 25/50; H01L 2224/83001; H01L 2224/8322

(57) ABSTRACT

According to various aspects and embodiments, a system and method for forming a packaged electronic device is disclosed. One example of the method comprises treating a surface of a first substrate to create a first surface having a low bond strength, at least a portion of the first surface defined by at least one three-dimensional structure and a layer of optical masking material, depositing a layer of structure material onto at least a portion of the first surface, bonding a second substrate to at least a portion of the layer of structure material, and separating the first substrate from the second substrate along the first surface.

### CROSS-REFERENCE TO RELATED APPLICATIONS

This application claims the benefit of priority under 35 U.S.C. §119(e) to co-pending U.S. Provisional Application No. 62/299,129 filed on Feb. 24, 2016, which is incorporated herein by reference in its entirety for all purposes.

### BACKGROUND

Technical Field

The present invention relates generally to the field of semiconductor wafer processing technology. In particular, aspects and embodiments of the present invention relate to a reusable template substrate that can be used in the process for manufacturing packaged electronic devices, such as semiconductor devices, as well as MEMS devices and microfluidic devices.

Background Discussion

Polymer materials are useful in a wide variety of technical applications, such as wafer-level packaging, semiconductor electronic device fabrication, and microfluidic systems. However, the processing used to incorporate these organic materials into other systems, such as wafer-level packages for electronic devices, can often times be incompatible with the processing used to form other components of these systems. Furthermore, the profit margins for products that incorporate these materials can often be quite small. Thus, any advantage that can be used to reduce both manufacturing costs and process inefficiencies would be beneficial.

### SUMMARY

Aspects and embodiments are directed to systems and methods for transferring three-dimensional (3D) structures from a reusable template substrate.

According to one aspect of the present invention there is provided a method of forming a packaged electronic device. The method comprises treating a surface of a first substrate to create a first surface having a low bond strength, at least a portion of the first surface defined by at least one three-dimensional structure and a layer of optical masking material, depositing a layer of structure material onto at least a portion of the first surface, bonding a second substrate to at least a portion of the layer of structure material, and separating the first substrate from the second substrate along the first surface.

In some embodiments, the method further comprises removing at least a portion of the structure material prior to bonding the second substrate.

In some embodiments, the second substrate is bonded to a first portion of the layer of structure material and the method further comprises removing a second portion of the structure material prior to bonding the second substrate to the first portion.

In some embodiments, removing includes exposing the second portion of the structure material to a source of light.

In some embodiments, exposing the second the second portion of the structure material includes directing the source of light through a second surface of the first substrate, the second surface opposing the first surface.

In some embodiments, the layer of optical masking material blocks the light from a portion of the structure material.

In some embodiments, the layer of optical masking material blocks the light from the first portion of the structure material.

In some embodiments, removing further includes exposing the first portion of the structure material to a developing material.

In some embodiments, treating the surface of the first substrate includes depositing a layer of temporary bonding material onto the first surface.

In some embodiments, removing the first substrate includes removing the temporary bonding material.

In some embodiments, removing the temporary bonding material includes exposing the temporary bonding material to a release agent.

In some embodiments, the at least one three-dimensional structure includes at least one recessed portion.

In some embodiments, the layer of optical masking material is formed within the at least one recessed portion.

In some embodiments, the layer of structure material is deposited on at least one recessed portion and at least one raised portion of the three-dimensional structure.

In some embodiments, the layer of structure material that is deposited on the at least one recessed portion and the at least one raised portion defines at least one cavity when the second substrate is bonded to the structure material.

In some embodiments, the second substrate is bonded to the layer of structure material that is deposited on the at least one raised portion.

In some embodiments, the second substrate includes at least one electronic device disposed on a portion of a surface of the second substrate that is within the at least one cavity.

In some embodiments, the method further comprises forming at least one bonding structure on at least a portion of the structure material.

In some embodiments, the method further comprises dicing the second substrate to form a plurality of packaged electronic devices.

In some embodiments, the method further comprises mounting the at least one electronic device in an electronic device module.

In some embodiments, the method further comprises reusing the first substrate for forming multiple electronic devices.

According to another aspect of the present invention, a method of forming a packaged electronic device comprises generating a three-dimensional structure using a first substrate, a surface of the first substrate having a topography that defines at least a portion of the three-dimensional structure, and transferring the three-dimensional structure to a second substrate.

According to another aspect of the present invention, a method of forming a reusable template wafer is provided. The method comprises masking a first portion of a surface of a substrate, selectively removing a second portion of the surface of the substrate to create at least one recess having a first depth, masking a third portion of the surface of the substrate, selectively removing a fourth portion of the surface of the substrate to create at least one recess having a second depth, and depositing a layer of optical masking material on at least a portion of the at least one recess having the second depth.

In some embodiments, the at least one recess having the second depth is positioned within the at least one recess having the first depth.

According to another aspect of the present invention, a reusable template wafer is provided. In some embodiments, the reusable template wafer is used in forming an electronic device. The reusable template wafer comprises a substrate having a first surface defined by a three-dimensional topography, and a layer of optical masking material disposed on at least a portion of the first surface.

In some embodiments, the layer of optical masking material is disposed in at least a portion of at least one recessed portion of the three-dimensional topography.

In some embodiments, the at least one recessed portion includes a first portion having a first depth and a second portion having a second depth that is different than the first depth.

In some embodiments, the second portion is within the first portion.

In some embodiments, the layer of optical masking material is disposed on the second portion.

In some embodiments, the layer of optical masking material is further disposed on at least one surface of a raised portion of the three-dimensional topography.

In some embodiments, at least a portion of the first surface has a low bond strength.

In some embodiments, the low bond strength is created by a layer of temporary bonding material disposed on the first surface and the layer of optical masking material.

In some embodiments, the temporary bonding material is polyvinyl alcohol (PVA).

In some embodiments, the temporary bonding material is a halocarbon.

In some embodiments, the at least one three-dimensional structure includes a first raised portion having dimensions of a first size and a second raised portion having dimensions of a second size.

In some embodiments, the substrate is constructed from a material that is UV transparent.

In some embodiments, the UV transparent material is lithium nitrate.

In some embodiments, the reusable template wafer further comprises a layer of structure material disposed on at least a portion of the first surface.

In some embodiments, the layer of structure material is a polymer.

In some embodiments, the polymer is a polyimide.

In some embodiments, the polymer is photosensitive.

In some embodiments, the layer of structure material has a thickness in a range of from about three to about five microns.

In some embodiments, the reusable template wafer further comprises a device wafer substrate attached to at least a portion of the layer of structure material.

In some embodiments, a portion of the layer of structure material not attached to the device wafer substrate defines a cavity formed adjacent a portion of the device wafer substrate.

In some embodiments, the device wafer substrate includes an acoustic wave filter disposed on a portion of a surface of the device wafer substrate that is within the cavity.

In some embodiments, the device waver substrate includes interdigitated electrodes of an acoustic wave filter disposed on a surface of the device wafer substrate that is within the cavity.

Still other aspects, embodiments, and advantages of these example aspects and embodiments, are discussed in detail below. Moreover, it is to be understood that both the foregoing information and the following detailed description are merely illustrative examples of various aspects and embodiments, and are intended to provide an overview or framework for understanding the nature and character of the claimed aspects and embodiments. Embodiments disclosed herein may be combined with other embodiments, and references to “an embodiment,” “an example,” “some embodiments,” “some examples,” “an alternate embodiment,” “various embodiments,” “one embodiment,” “at least one embodiment,” “this and other embodiments,” “certain embodiments,” or the like are not necessarily mutually exclusive and are intended to indicate that a particular feature, structure, or characteristic described may be included in at least one embodiment. The appearances of such terms herein are not necessarily all referring to the same embodiment.

### BRIEF DESCRIPTION OF DRAWINGS

Various aspects of at least one embodiment are discussed below with reference to the accompanying figures, which are not intended to be drawn to scale. The figures are included to provide an illustration and a further understanding of the various aspects and embodiments, and are incorporated in and constitute a part of this specification, but are not intended as a definition of the limits of any particular embodiment. The drawings, together with the remainder of the specification, serve to explain principles and operations of the described and claimed aspects and embodiments. In the figures, each identical or nearly identical component that is illustrated in various figures is represented by a like numeral. For purposes of clarity, not every component may be labeled in every figure. In the figures:

FIG. 1 is a cross-sectional side view of a first example of a template wafer with a transferable structure that is attached to a device wafer according to aspects of the invention;

FIG. 2A is a flow chart illustrating an embodiment of a method according to aspects of the invention;

FIG. 2B is a flow chart illustrating an embodiment of a method for implementing one of the steps of FIG. 2A;

FIG. 2C is a flow chart illustrating an embodiment of a method for implementing one of the steps of FIG. 2A;

FIG. 3A illustrates the result of the method of FIG. 2B according to a first example;

FIG. 3B illustrates an act in the method of FIG. 2A according to the first example;

FIG. 3C illustrates an act in the method of FIG. 2A according to the first example;

FIG. 3D illustrates an act in the method of FIG. 2A according to the first example;

FIG. 3E illustrates an act in the method of FIG. 2A according to the first example;

FIG. 3F illustrates an act in the method of FIG. 2A according to the first example;

FIG. 4A illustrates the result of the method of FIG. 2B according to a second example;

FIG. 4B illustrates an act in the method of FIG. 2A according to the second example;

FIG. 4C illustrates an act in the method of FIG. 2A according to the second example;

FIG. 4D illustrates an act in the method of FIG. 2A according to the second example;

FIG. 4E illustrates an act in the method of FIG. 2A according to the second example;

FIG. 4F illustrates an act in the method of FIG. 2A according to the second example;

FIG. 5 is a cross-sectional side view of another example of a template wafer with a transferable structure according to aspects of the invention;

FIG. 6A illustrates an example of an act according to a method in accordance with aspects of the invention;

FIG. 6B illustrates an example of an additional act according to the method of FIG. 6A;

FIG. 7 is a cross-sectional side view of another example of a template wafer with a transferable structure according to aspects of the invention;

FIG. 8A is a cross-sectional side view of another example of a template wafer with a transferable structure according to aspects of the invention;

FIG. 8B illustrates an example of an additional act performed on the example structure shown in FIG. 8A;

FIG. 8C illustrates an example of an additional act performed on the example structures shown in FIG. 8B;

FIG. 9A is a cross-sectional side view of another example of a template wafer with a transferable structure according to aspects of the invention;

FIG. 9B illustrates an example of an additional act performed on the example structure shown in FIG. 9A;

FIG. 9C illustrates an example of an additional act performed on the example structures shown in FIG. 9B;

FIG. 10A is cross-sectional side view of another example of a template wafer with a transferable structure according to aspects of the invention;

FIG. 10B is a cross-sectional side view of another example of a template wafer with a transferable structure according to aspects of the invention;

FIG. 11 is a block diagram of one example of an antenna duplexer incorporating a packaged electronic device according to aspects of the present invention;

FIG. 12 is a block diagram of one example of a module incorporating a packaged electronic device according to aspects of the present invention; and

FIG. 13 is a block diagram of one example of a communication device incorporating the antenna duplexer of FIG. 11, according to aspects of the invention.

### DETAILED DESCRIPTION

Polymer structures of varying sizes and shapes for use in different applications, such as wafer-level packaging, electronic device fabrication, microfluidic systems, etc., can be created using any one of a number processing techniques, including those typically used in semiconductor fabrication, such as film coating and/or layering, photosensitive film patterning, etching, bonding, etc. However, the temperatures and chemicals used to create these polymer structures may be incompatible with the processes used to create the devices or systems into which these structures are integrated. Furthermore, many of the applications that the polymer structures are used in create products that are cost-sensitive, so executing a structure with fewer processing steps can reduce costs.

Disclosed herein are examples related to the use of three-dimensional (3D) polymer structures for use in wafer-level packaging for semiconductor devices, although the systems and methods disclosed herein may also be applied to other applications that may utilize polymer structures, such as electronic and optoelectronic device fabrication, MEMS devices, microfluidic and biomedical devices and systems, and the like. According to some embodiments, the polymer material may be processed to create 3D polymer micro-structure features that are micrometer or larger in scale. In certain instances, the processes used to produce these 3D structures can include polymer film coating, photosensitive film patterning, wafer-to-wafer bonding, etc. Typical processing methods for creating these structures include fabricating the polymer material directly on a device wafer, or by undergoing multiple transfers of individual polymer layers onto the device wafer. The embodiments disclosed herein include the use of a recyclable template structure or template wafer having at least one surface with a 3D topography that may be used to create the 3D polymer structures that may then be transferred and attached to a device substrate. This approach addresses many of the problems associated with typical processing methods mentioned above. The systems and methods disclosed herein allow for complex, multi-level structures with features of varying sizes and shapes to be created. The 3D polymer structures may therefore be created externally from one or more other components of the electronic device and packaging. This not only alleviates issues related to incompatible processing methods, but also reduces costs by consolidating the processing steps used to create the polymer structure and by reusing the specialized template over and over again in multiple processes. Other process efficiencies are also achieved through the disclosed method, including the elimination of the alignment used in between deposition steps of the typical approaches.

It is to be appreciated that the aspects disclosed herein in accordance with the present invention are not limited in their application to the details of construction and the arrangement of components set forth in the following description or illustrated in the accompanying drawings. These aspects are capable of assuming other embodiments and of being practiced or of being carried out in various ways. Examples of specific implementations are provided herein for illustrative purposes only and are not intended to be limiting. In particular, acts, components, elements, and features discussed in connection with any one or more embodiments are not intended to be excluded from a similar role in any other embodiments.

Also, the phraseology and terminology used herein is for the purpose of description and should not be regarded as limiting. Any references to examples, embodiments, components, elements or acts of the systems and methods herein referred to in the singular may also embrace embodiments including a plurality, and any references in plural to any embodiment, component, element or act herein may also embrace embodiments including only a singularity. References in the singular or plural form are not intended to limit the presently disclosed systems or methods, their components, acts, or elements. The use herein of “including,” “comprising,” “having,” “containing,” “involving,” and variations thereof is meant to encompass the items listed thereafter and equivalents thereof as well as additional items. References to “or” may be construed as inclusive so that any terms described using “or” may indicate any of a single, more than one, and all of the described terms. In addition, in the event of inconsistent usages of terms between this document and documents incorporated herein by reference, the term usage in the incorporated reference is supplementary to that of this document; for irreconcilable inconsistencies, the term usage in this document controls.

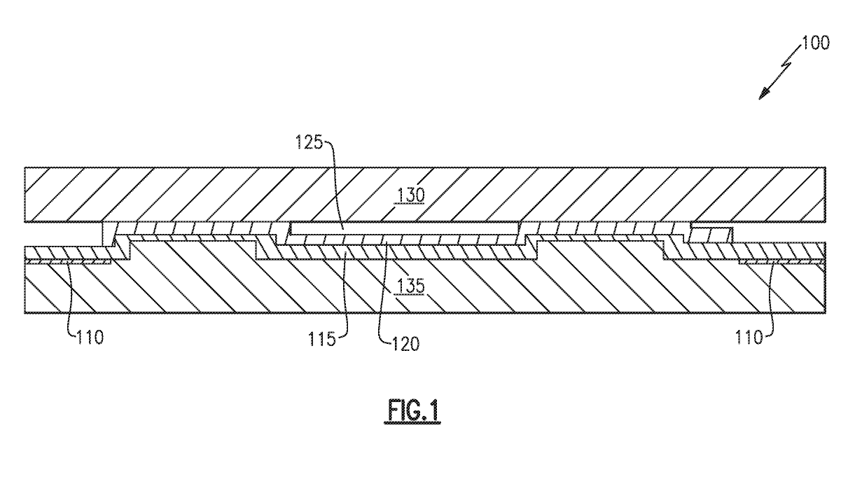

In accordance with some embodiments, FIG. 1 illustrates a side view of a cross-section of a template wafer substrate 135 with a transferable structure 120 attached to a device wafer substrate 130, generally indicated at 100. A layer of temporary bonding material 115 is deposited on the surface of the template wafer substrate 135. When the temporary bonding material 115 is removed, the template wafer 135 may also be removed, leaving the transferable structure 120 (also referred to below as a layer of structure material) attached to the device wafer substrate 130. As explained further below, the shape and size of the transferable structure 120 is at least partially defined by the topography of the surface of the template wafer substrate 135. This allows for various features of the packaged device to be processed separately and then transferred to the device wafer substrate 130. For example, once bonded or otherwise attached to the device wafer substrate 130, the transferable structure 120 may form a cavity 125 that can be used to hermetically seal or otherwise encapsulate one or more electronic devices housed within the cavity 125. For example, one or more electronic devices may be disposed on a surface of the device wafer substrate 130 that is within the cavity 125. Non-limiting examples of electronic devices include semiconductor die, MEMS devices, and other electrical components that may be used according to one or more embodiments of the present invention. In certain instances, the electronic device may include or be part of a larger system, as discussed further below. Non-limiting examples of electronic devices include MEMS or acoustic wave devices, such as surface acoustic wafer (SAW) filters or bulk acoustic wave (BAW) filters, or other similar acoustic wave components. For example, interdigitated transducer (IDT) electrodes of a SAW filter may be disposed on the device wafer substrate 130 within the cavity 125. The surface of the template wafer substrate 135 may also include optical masking material 110 that may be used to define at least a portion of the shape and size of the transferred structure 120, as discussed in further detail below.

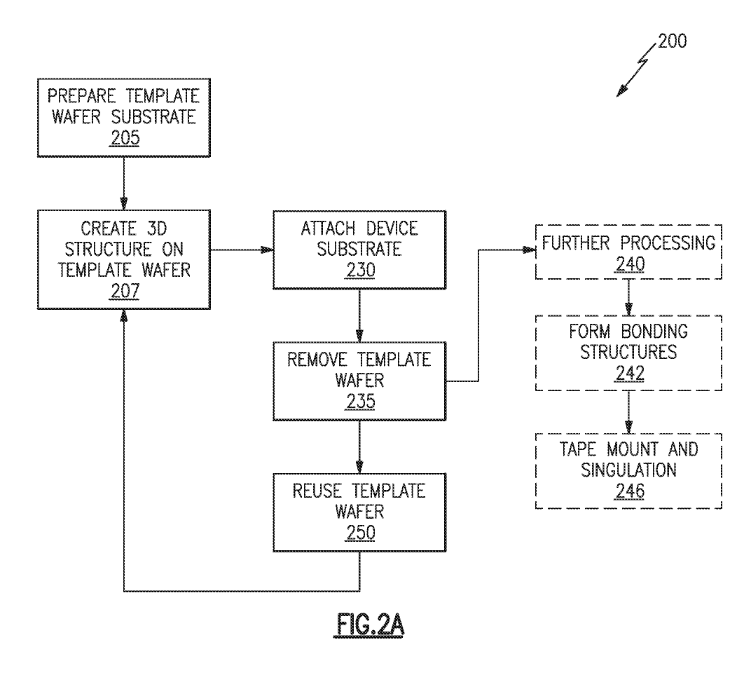

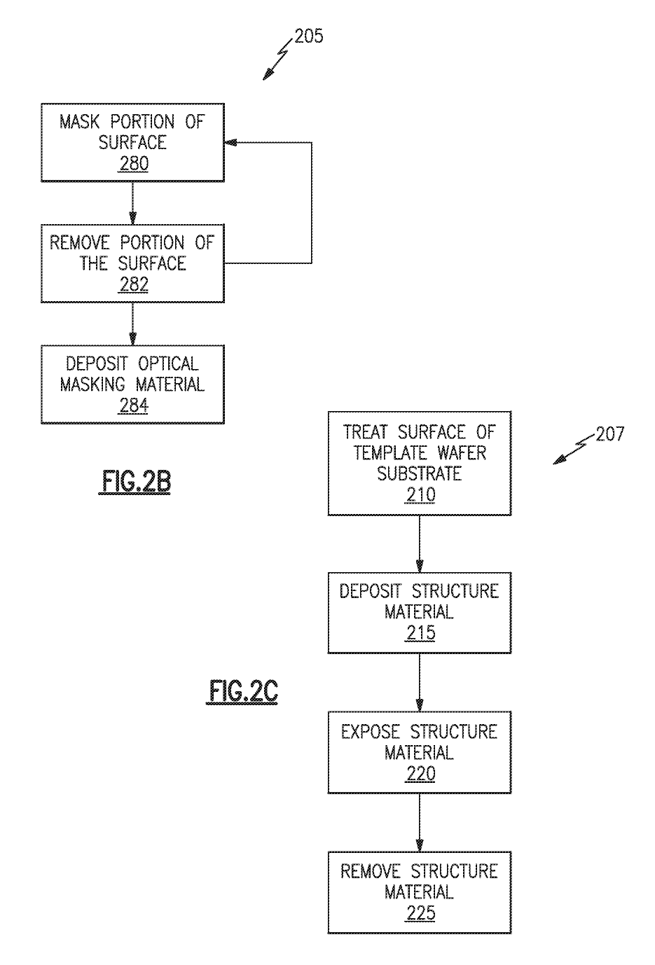

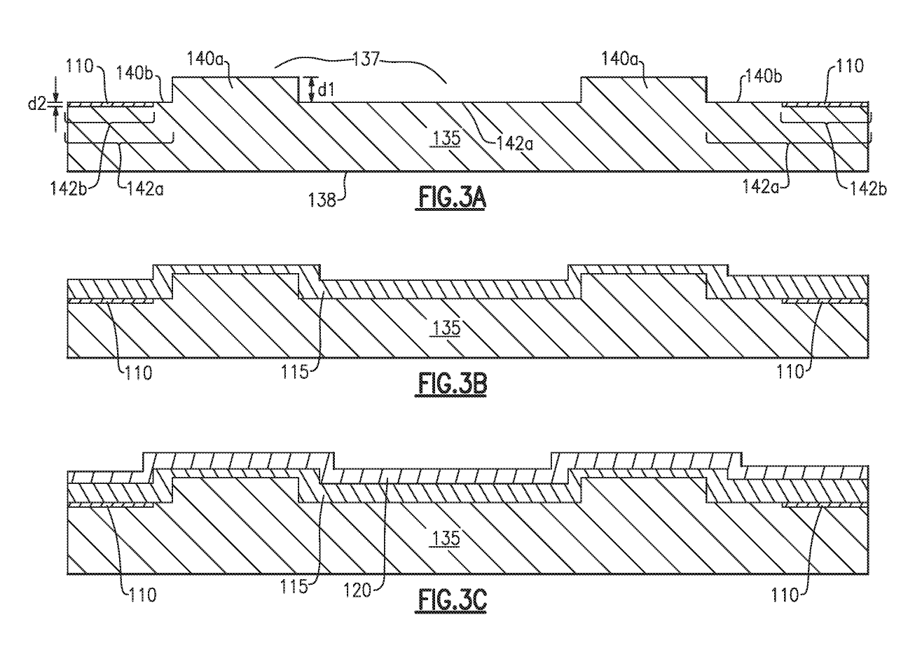

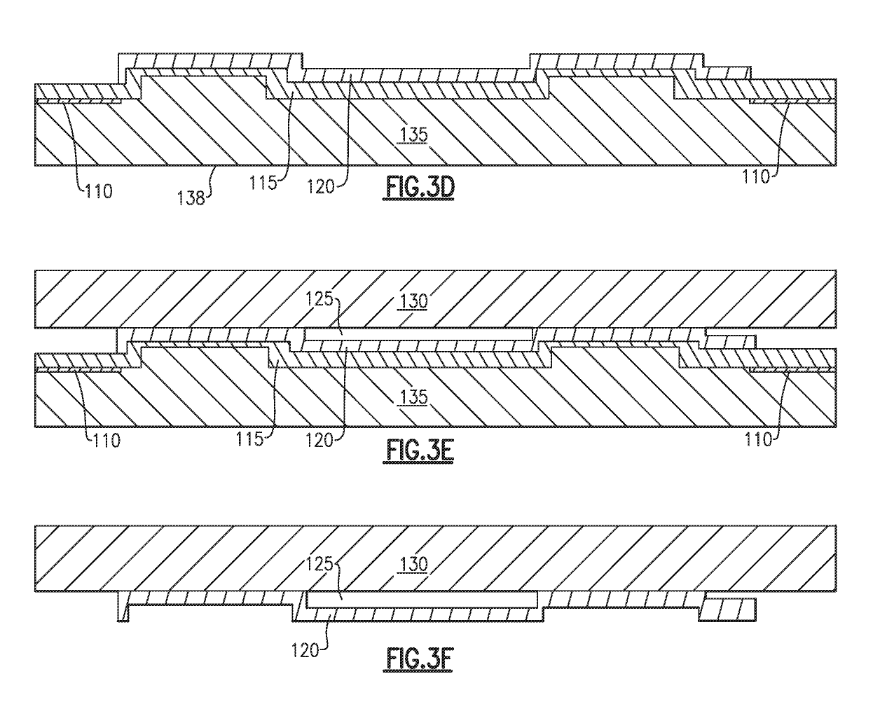

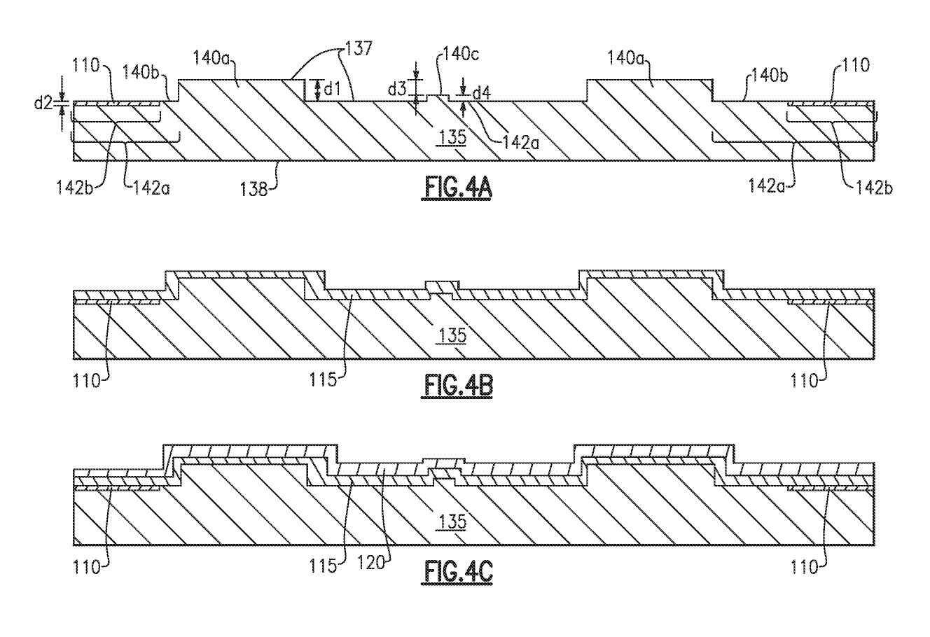

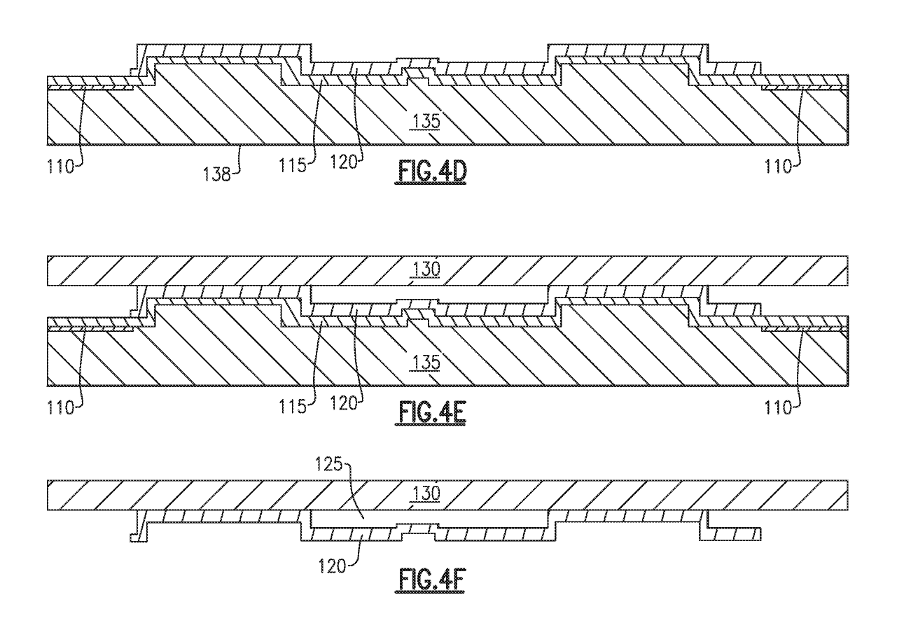

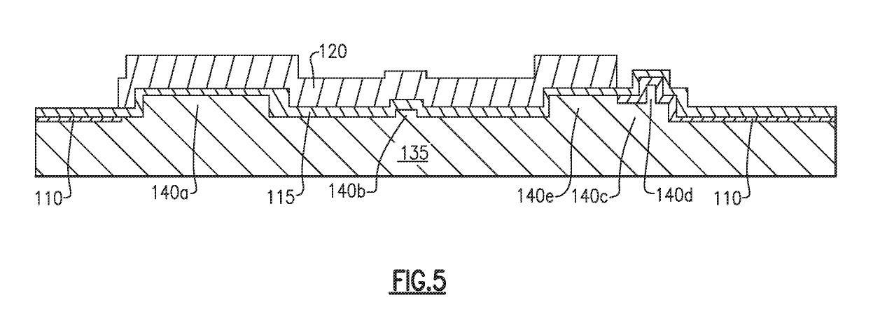

According to various aspects and embodiments, FIG. 2A illustrates a flow diagram of one example of a method 200 of forming a packaged electronic device, and includes one or more of the elements discussed above in reference to FIG. 1. Process 200 is described below in reference to FIGS. 3A-3F and 4A-4F. Although the discussion below references a single package, it is to be understood that the method may be applied to forming multiple packages on a common substrate or wafer. For example, step 246 includes singulation, where the device wafer substrate may be diced to individually separate the packaged electronic devices from one another.

A first step 205 includes preparing a template wafer substrate 135, such as the template wafer substrate 135 shown in FIGS. 3A and 4A. According to some embodiments, the template wafer substrate 135 may be constructed from a material that is transparent to UV light. Non-limiting examples of UV transparent materials include silicon carbide (SiC), sapphire, silicon nitride (SiN), and quartz.

FIG. 2B illustrates one example process 205 for preparing the template wafer substrate 135. The process starts at step 280 by masking at least a portion of an upper or first surface 137 (see FIGS. 3A and 4A) of the template wafer substrate 135. Masking may be performed using any one of a number of different techniques, such as by using a photolithographic method, or by using a shadow mask. For example, a photolithographic method may comprise depositing a layer of photolithographic resist material, also referred to herein as simply “photoresist,” on the entire surface of the template wafer substrate 135 using a spin-coat technique, which is followed by positioning a photomask over the layer of photoresist material, as will be recognized by those of skill in the art. Light may be applied through the photomask to the underlying photoresist material, thereby causing a chemical reaction to portions of the photoresist material that correspond to a desired pattern defined by the photomask. In certain instances, the light polymerizes the photoresist material, thereby hardening it and making it resistive to certain solvents and allowing it to protect the surface of the template wafer substrate 135 underneath. In step 282, a portion of the surface of the template wafer substrate 135 is removed. For instance, the surface of the template wafer may be etched using a wet etch process by exposing the surface to one or more solvents, which may etch away the unreacted photoresist material (if not removed in a separate step) and at least some of the underlying material that forms the template wafer substrate 135. In other examples, a dry etch process may be used, as understood by those of skill in the art. The reacted portion of the photoresist material may also be removed in a separate step.

The resulting surface topography of the template wafer substrate 135 after undergoing the masking 280 and removal 282 processes includes three-dimensional structures, thereby creating a surface with a 3D topography. For example, one or more raised portions 140a correspond to the “protected” regions underneath the reacted (exposed) photoresist material, and one or more recessed portions 142a and 142b correspond to the “unprotected” regions underneath the unreacted (unexposed) photoresist material.

According to the example shown in FIG. 3A, the template wafer substrate 135 actually undergoes at least two masking 280 and removal 282 steps to create the 3D topography. The first masking and removal process results in a raised portion of the 3D structure corresponding to 140a and a recessed portion corresponding to 142a, with d1 indicating the depth of the material removed from the surface of the template wafer substrate 135, which is also the height of the raised portion 140a. In certain instances this height may have a value of about 5 microns to about 10 microns. As indicated by the arrow in FIG. 2B, the mask and removal process may be repeated, with the next repetition using a mask with a different pattern that results in features with different dimensions. This allows for different portions of the surface of the substrate to be exposed to light and different portions to be removed. For instance, the second masking and removal process results in a raised portion 140b and a recessed portion 142b having a depth (d2), which in various embodiments corresponds with the thickness of the layer of optical masking material 110, discussed further below. For example, in some embodiments, d2 has a depth in a range of about 500 Angstroms to about 1 micron. The mask used in this second process is therefore dimensioned to “protect” both raised portions 140a and 140b and recessed portion 142a. According to other embodiments, the second masking and removal step is not performed, as the layer of optical masking material 110 is deposited directly on at least a portion of the recessed portion of the template wafer 135 surface formed in the first removal step. For example, this may be the case in instances where a thin layer of optical masking material 110 is used.

The masking 280 and removal 282 steps may thus be repeated multiple times to create three-dimensional structures corresponding to raised and recessed features formed by the material comprising the surface of the template wafer substrate 135. For instance, the example shown in FIG. 4A includes raised portion 140c that may be formed by masking the same regions in the first masking process as discussed above in reference to FIG. 3A, and then performing a less aggressive etch or removal process corresponding to depth d3. Then a mask may be used to protect the raised portion 140c and the remainder of the etch or removal may be performed corresponding to depth d4. According to some embodiments, the masking and removal processes are performed such that the height (d4) of the raised feature 140c is from about 1 micron to about 2 microns. In accordance with at least one embodiment, the raised feature 140c may function as an anti-stiction dimple, so that the layer of structure material 120 (discussed further below) may be removed from the template wafer 135 more easily by decreasing surface tension.

Although the examples discussed above use a photolithographic masking process, other masking techniques are also within the scope of this disclosure, such as shadow masks, as will be appreciated by those skilled in the art. The masking and removal steps can be repeated multiple times, using masks with “open” regions (i.e., where light can pass through) and “closed” regions (i.e., where light is blocked) of varying dimensions to achieve a desired 3D topography on the surface of the template wafer 135. This allows for flexibility in design and for potentially endless variations in the sizes and shapes of the raised and recessed portions comprising the 3D topography of the surface of the template wafer and the resulting 3D structure that is created using this surface. Rounded, stepped, and features with “slanted,” nonlinear, and/or continuously varying surfaces may also be created.

Referring back to FIG. 2B, step 284 includes depositing a layer of optical masking material 110 (FIGS. 3A and 4A) onto at least a portion of the surface of the template wafer substrate 135. The optical masking material 110 functions to block light when a light source is applied to a bottom or second surface 138 of the template wafer substrate 135. Non-limiting examples of suitable optical masking materials include chrome or chrome-based materials such as chrome oxide, chrome oxynitride, titanium, tungsten, and the like. Other materials are also within the scope of this disclosure, so long as they are suitable for blocking light of a desired wavelength(s) and they do not otherwise interfere with processing and/or functionality of the methods and systems described herein. The optical masking material 110 may be deposited using any one of a number of different deposition techniques. For example, portions of the first surface 137 of the template wafer substrate 135 may be masked off where optical masking material is not desired, and then a layer of optical masking material 110 may be deposited using an evaporation or sputtering process, as understood by those skilled in the art. According to some embodiments, the layer of optical masking material 110 may have a thickness in a range of about 500 Angstroms to about one micron. The thickness of the optical masking material 110 may depend on the type of material used, and is therefore deposited at a thickness so as to provide the light-blocking function.

Referring back to FIG. 2A, at step 207 a 3D structure is created using the template wafer prepared in step 205. FIG. 2C illustrates one example process 207 for creating the 3D structure and is explained in further detail below.

At step 210, the template wafer substrate 135 prepared in step 205 is treated so that the first surface 137 has or is otherwise characterized by a low bond strength. A low bond strength allows for relative ease in the removal of the template wafer substrate 125 once the 3D structure has been transferred to the device wafer substrate 130. For example, according to one embodiment, a layer of temporary bonding material 115 may be deposited on the first surface 137 of the template wafer substrate 135 and the layer of optical masking material 110, as shown in FIGS. 3B and 4B. Non-limiting examples of temporary bonding material include polyvinyl alcohol (PVA), Omnicoat™ (commercially available from MicroChem Corp.), polymethylglutarimide (PMGI), and other low surface energy organic materials. According to some embodiments, the temporary bonding material 115 may be a halocarbon, such as tetrafluoromethane (CF4) or sulfur hexafluoride (SF6). According to some embodiments, the temporary bonding material 115 may be a material that is capable of being dissolved by selected solvents. The temporary bonding material 115 may be deposited using a spin-coat, and the thickness may be in a range of about 2000 Angstroms to several microns.

According to another embodiment, the first surface 137 is treated in a manner such that the physical surface exhibits low bonding strength properties. For example, instead of coating the first surface 137 with a material, the first surface 137 may undergo processing that renders the surface with a low bond strength.

At step 215, a layer of structure material 120 is deposited onto at least a portion of the template wafer substrate 135. In instances where a temporary bonding material 115 is used (FIGS. 3C and 4C), the layer of structure material 130 is deposited directly onto the temporary bonding material 115. In instances where the first surface 137 of the template wafer substrate 135 has been treated to exhibit low bonding strength properties, the layer of structure material 120 is deposited directly onto the first surface 137. According to certain aspects, the layer of structure material 120 may be deposited using spin coat or spray-on techniques. As shown in FIGS. 3C and 4C, the underlying 3D structure of the template wafer substrate 135 is “carried” or otherwise transferred through to the layer of structure material 120, such that raised and recessed portions are present in the upper and lower surfaces of the structure material 120. In certain instances, these features correspond to desired features of the packaging (or device itself) for the electronic devices of the device wafer substrate 130.

In accordance with at least one embodiment, the layer of structure material 120 may include one or more polymer materials. In some embodiments, the polymer material may be a polyimide material, such as polyimide resin. According to one embodiment, the polymer may be photosensitive such that when the material is exposed to light, such as ultraviolet (UV) light, the photosensitive material reacts. In certain instances, the UV light causes crosslinking between polymer chains that results in forming a stable polymeric network, thereby hardening the material. Non-limiting examples of photosensitive materials include photosensitive epoxies, polyimide, and epoxy-based photoresist materials, such as B-stage polymers. Some examples of these materials include SU-8 photoresist (commercially available from MicroChem Corp.), benzocyclobutene (BCB), and mr-I 9000 (commercially available form Micro Resist Technology Gmbh). In some embodiments, the thickness of the structure material 130 is from about 3 microns to about 5 microns, although other thicknesses are within the scope of this disclosure. As will be understood by those of skill in the art, the thickness of the structure material 120 may depend on the desired application.

In step 220 and as illustrated in FIGS. 3D and 4D, the layer of structure material 120 is exposed to light, such as UV light, thereby causing the exposed portions of the structure material 120 to at least partially polymerize. For example, the second surface 138 of the template wafer substrate 135 may be flood exposed with UV light. The light is blocked from the portions of the structure material 120 that are positioned “over” the layer of optical masking material 110, since the layer of optical masking material 110 reflects (or absorbs, depending on the material) the light. These portions of the structure material 120 remain unreacted, and may be removed in step 225 using any one of a number of different removal techniques, such as a wet etch process. According to one embodiment, portions of the unreacted structure material 120 may be removed using one or more organic solvents, such as an SU-8 developer material (commercially available from MicroChem Corp.) or propylene glycol methyl ether acetate (PGMEA), such as in instances where SU-8 is used as the structure material 120. According to various aspects, the layer of structure material 120 may also be baked prior to and/or after exposure to light. In some embodiments, exposing the layer of structure material 120 may be done in such a way as to not fully polymerize the structure material, e.g., by limiting the amount of time the material is subjected to light and/or limiting the intensity or wavelength(s) of light. For instance, a partial polymerization process may be performed such that the at least partially reacted structure material can withstand the removal process performed in step 225, but is in a state that allows for the at least partially reacted material to be bonded to the device wafer substrate 130 (discussed in further detail below), at which point it may be subjected to an additional exposure step or otherwise treated to “fully” react the material or otherwise render suitable for packaging.

At step 230, the device wafer substrate 130 is attached to at least a portion of the layer of structure material 120, as illustrated in FIGS. 3E and 4E. In certain instances, the layer of structure material 120 may be treated before or after exposure to light so as to render it capable of bonding, such as by performing a soft-cure step before bonding. For example, certain structure materials, such as photoresist, may be soft baked prior to exposure, and then after exposure undergo a post exposure bake (PEB) or may be otherwise treated to place the photoresist in a half-cured state (B stage) prior to bonding. Once developed, the photoresist may undergo a hard bake. For instance, SU-8 may be soft baked prior to exposure at 95° C. for a time period that depends on the thickness and the type of SU-8 material. The soft-cure step renders the photoresist material pliable and capable of conforming to the topology of the surface the material it is being bonded to. Once attached, the photoresist may be subjected to a hard bake to more fully cure the material (and thereby harden it), and to complete the crosslinking process. For example, SU-8 material may undergo a PEB process at temperatures of about 65° C. and/or about 95° C. for a time period that depends on the thickness and type of SU-8 material (e.g., from 1-5 minutes). After transfer, a hard bake may be performed at a temperature in a range of about 150° C. to about 250° C. for up to 30 minutes (depending on thickness and type of photoresist). According to some embodiments, the temperature and/or time may be reduced for the PEB and/or hard bake processes (as compared to the times and temperatures recommended by the material manufacturer). Soft-cure, PEB, and/or hard bake processes may also be used in instances where multiple layers of polymer are formed. For example, a first layer of polymer structure material may be partially cured, and then a second layer of polymer structure material may be deposited on top of the first layer. Once transferred, both layers may be hardened by performing a hard bake process.

As illustrated in FIGS. 3E and 4E, the device wafer substrate 130 may be bonded to raised portions of the structure material 120, thereby creating a cavity 125 that is bounded by at least a portion of the device wafer substrate 130 and a recessed portion of the structure material 120 (using the template wafer substrate 135 as a frame of reference). Although not explicitly shown, one or more electronic devices may be disposed on the surface of the device wafer substrate 130 that resides within the cavity 125, and therefore portions of the structure material 120 may surround the cavity 125. For example, raised portion 140a may form a ring or any other shape that circumscribes the perimeter of the region forming the cavity 125.

In some embodiments, the device wafer substrate 130 is bonded to the layer of structure material 120 at an elevated temperature under pressure for a predetermined length of time. For instance, when SU-8 is used as the structure material 120, the bonding conditions may be at a temperature from about 150° C. to about 300° C. and a pressure of from about 0.5 MPa to about 2 MPa for a time of from about 5 minutes to about 45 minutes. In one embodiment, the bonding conditions are performed such that they are appropriate for B-stage SU-8. In addition, the bonding process may be performed under vacuum conditions. In certain instances, this may create a cavity 125 that is also under vacuum pressure. According to some embodiments, additional pressure does not need to be applied during the bonding process.

Although FIGS. 3E and 4E indicate that portions of the layer of structure material 120 are bonded directly to the device wafer substrate 130, according to some embodiments, the structure material 120 may be bonded to features or structures already disposed on the device wafer substrate 130, such as bonding or sealing structures, or other features that contribute to the functionality of the package and/or electronic device disposed on the device wafer substrate 130. One or more of these features may require processing that is not conducive to the layer of structure material 120 (or vice versa), and therefore it may be advantageous to create and attach the material forming the 3D structure separately.

At step 235, the template wafer substrate 135 may be removed or otherwise separated from the device wafer 130, thereby leaving the layer of structure material 120 attached to the device wafer substrate 130, as illustrated in FIGS. 3F and 4F. For instance, the template wafer substrate 135 may be separated form the device wafer 130 along the first surface 137 of the template wafer having the low bond strength. The temporary bonding material 115 may be removed using any one of a number of different removal techniques, such as by exposing or otherwise contacting the temporary bonding material 115 with a release agent, such as a solvent and/or through a thermal process, such as by exposing the temporary bonding material 115 to heat. In certain instances PMGI may be used to remove Omnicoat™. According to some embodiments, the release agent may be an inorganic solvent, such as water. For example, PVA may be dissolved in water. According to some embodiments, a “dry” transfer is performed, meaning that the template wafer substrate 135 is removed without the use of any liquids, such as liquid bonding materials and/or solvents.

Once removed, the template wafer substrate 135 may be optionally cleaned and then reused (step 250), as illustrated in FIG. 2A. For example, in some embodiments, the template wafer substrate 125 may return to step 210 of process 207 shown in FIG. 2C, where the low bonding characteristics of the first surface 137 are re-applied or re-established, for example, by depositing a layer of temporary bonding material 115. In other embodiments, the low bonding characteristics of the first surface 137 are preserved during the removal step 235, and the template wafer substrate 135 may return directly to step 215 of process 207 shown in FIG. 2C, where a layer of structure material 120 may be deposited. Since the 3D topography of the first surface 137 is preserved during steps 210-235, the template wafer substrate 135 does not have to undergo the preparation step performed in step 205. This creates efficiencies in both manufacturing costs and process times.

Steps 240, 242, and 246 of FIG. 2A may optionally be performed using the device wafer substrate 130 with the attached layer of structure material 120. For example, in step 240 other layers of material may be added and/or removed that provide functionality to the electronic devices or packaging that houses the devices. In step 242, bonding structures may be added to the device wafer. For instance, according to some embodiments, via openings may be formed through the layer of structure material 120 surrounding the cavity 125 that extend to the underlying device wafer substrate 130 (or bonding structures formed thereon). These vias may subsequently be filled with conductive material, such as metal. In certain instances, these bonding structures, such as the conductive vias, form the electrical contact between elements of the package, such as the electrical devices disposed within the cavity, and the outside of the package. According to other embodiments, sealing structures may be added to regions of the device wafer substrate 130 that are outside the cavity 125. These may aid in sealing the packaged device from external environments outside the package. Step 246 includes tape mounting the packaged devices to an adhesive-coated tape, and then performing singulation using a die cutting process.

In accordance with some embodiments, multiple transfers of 3D structure material may be performed. For instance, a first transferred layer of structure material may have a first composition of one or more polymers, and a second transferred layer of structure material may have a composition of one or more polymers that is different than the first layer. According to other embodiments, multiple layers of different polymer compositions may be deposited so that the single transferred 3D structure includes these different compositions. According to a further aspect, the transferred 3D structure may include layers with varying shapes and sizes. For instance, one layer of structure material included in a single transferred structure may have 3D features of certain sizes and shapes, and another layer of polymer material included in the same transferred structure may have 3D features of different sizes and shapes, and/or a different composition of polymer material.

The template wafer substrate 135 of FIG. 5 illustrates one example of the flexibility of the methods disclosed herein in the ability to form 3D topographies having many different features with varying sizes and shapes. For instance, the upper surface of the template wafer substrate 135 includes at least five different raised portions, which for the sake of convenience have been labeled 140a-140e, with each raised portion having a different height. In accordance with some embodiments, the raised feature labeled 140d in FIG. 5 may be used as a standoff during the bonding process to the device wafer substrate 130 for the purposes of preventing excessive force from being applied to the layer of structure material 120. Multiple similar standoffs may also be fabricated on the surface of the template wafer substrate 135 for each packaged device, with the total height of each standoff and the layer of temporary bonding material 115 deposited on top of the standoff being lower than the top surface of the layer of structure material 120 (as shown in FIG. 5). Further, the recessed portions of different depths are also shown, such as the portions of the surface that are covered by the layer of optical masking material 110. As shown, the optical masking material 110 may be applied in a three-dimensional manner so as to cover the sides of the standoff feature 140d. This may add structural support to the standoff 140d and/or may assist in preventing structural material 120 from reacting in the region outside of raised portion 140e.

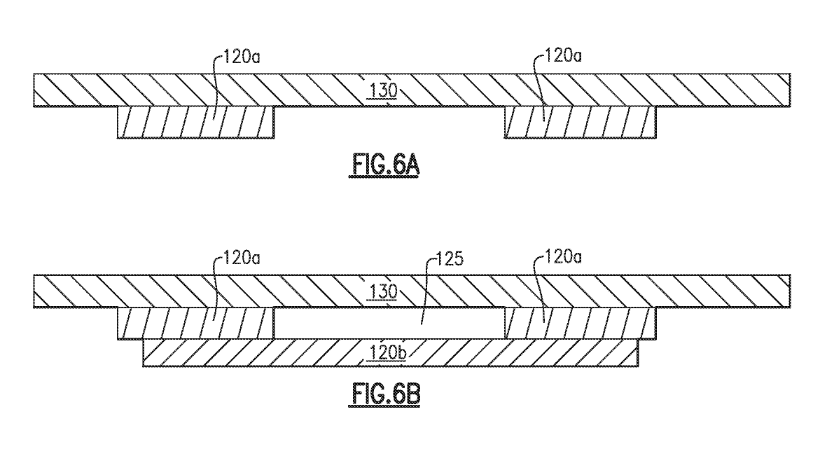

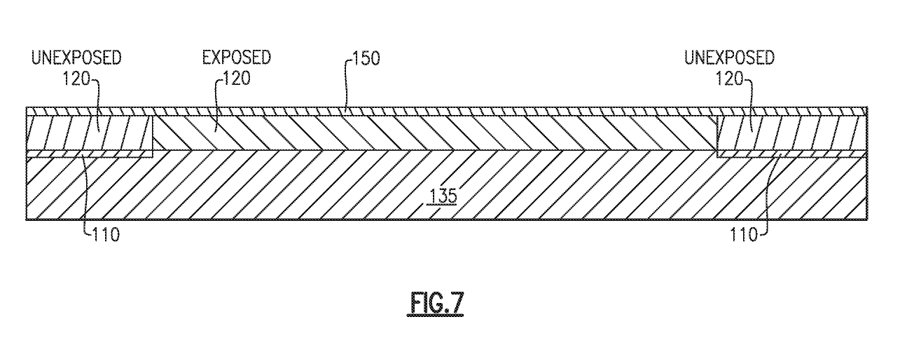

FIGS. 6A and 6B illustrate an embodiment that includes transferring 3D structures with different functionality to a device wafer substrate 130. According to some embodiments, 3D structures with different functionality may be transferred to components already disposed on the device wafer substrate 130. For example, FIG. 6A illustrates an instance where a first 3D structure made from a first structure material 120a may be transferred to the device wafer substrate 130 using the process outlined in steps 210-235 to form the “walls” of a cavity 125 (see FIG. 6B). A second 3D structure may be made from a second structure material 120b and bonded to the first structure material 120a to form a “lid” to the cavity 125, as shown in FIG. 6B. According to some embodiments, the second structure material 120b may have a different composition or may be a different material than the first structure material 120a. According to other embodiments, the second structure material 120b may have the same composition as the first structure material 120a, but may have undergone different processing, such as a longer or shorter exposure time during step 220. For instance, the structure material 120b forming the lid of the cavity may be fully cured or otherwise fully reacted so as to lessen the degree of outgassing into the cavity 125. This may lead to enhanced lifetime and/or other positive functional effects to the electronic or micro mechanical device(s) disposed within the cavity 125.

According to an additional aspect, FIG. 7 illustrates an embodiment where, instead of dissolving or otherwise removing the unexposed or otherwise unreacted portions of the structure material after exposure to the light source, these unexposed portions are allowed to remain so as to allow for a planar surface upon which another separate material 150, such as a metal, may be deposited on top of both of the upper surfaces of the unexposed and exposed portions of the structure material 120. The additional material 150 may be deposited using various techniques, such as evaporation, spin-coating, spraying, etc., or may simply be prepared separately as a unitary object and then bonded to the structure material 120. This process allows for structures to be formed directly on a metal lid. Although not explicitly shown in FIG. 7, a layer of temporary bonding material 115 may be deposited onto the template wafer substrate 135 prior to deposition of the structure material 120, thereby allowing the metal lid and accompanying structure material to be removed. According to an alternative embodiment, a layer of metal may be formed on a template wafer substrate 135 that is coated with a layer of temporary bonding material 115. One or more layers of structure material 120 may then be formed on the layer of metal, which results in a structure that may function as a lid. This lid structure may be removed from the template wafer substrate 135 and transferred to a device wafer substrate 130 as discussed herein.

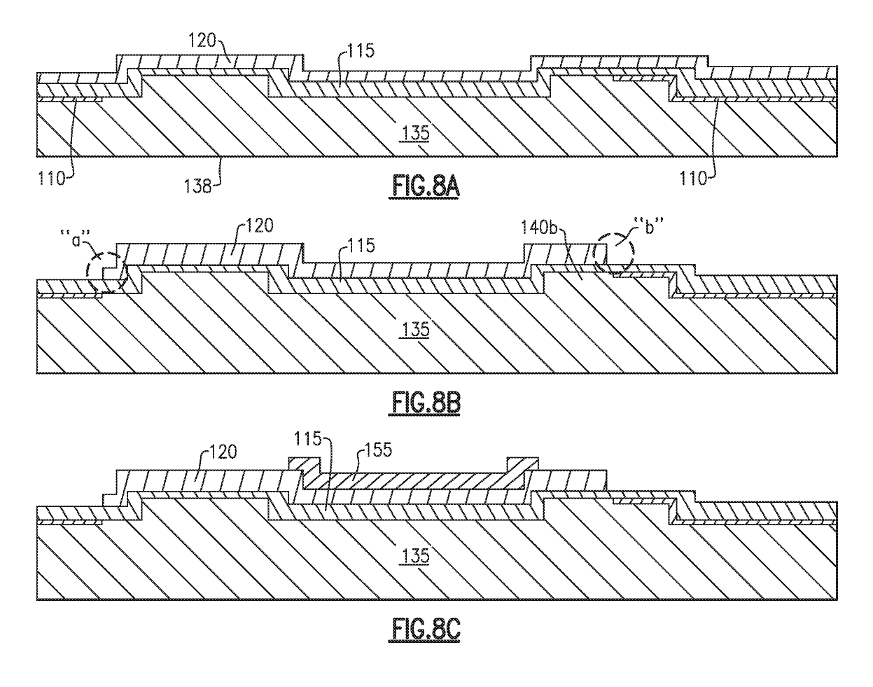

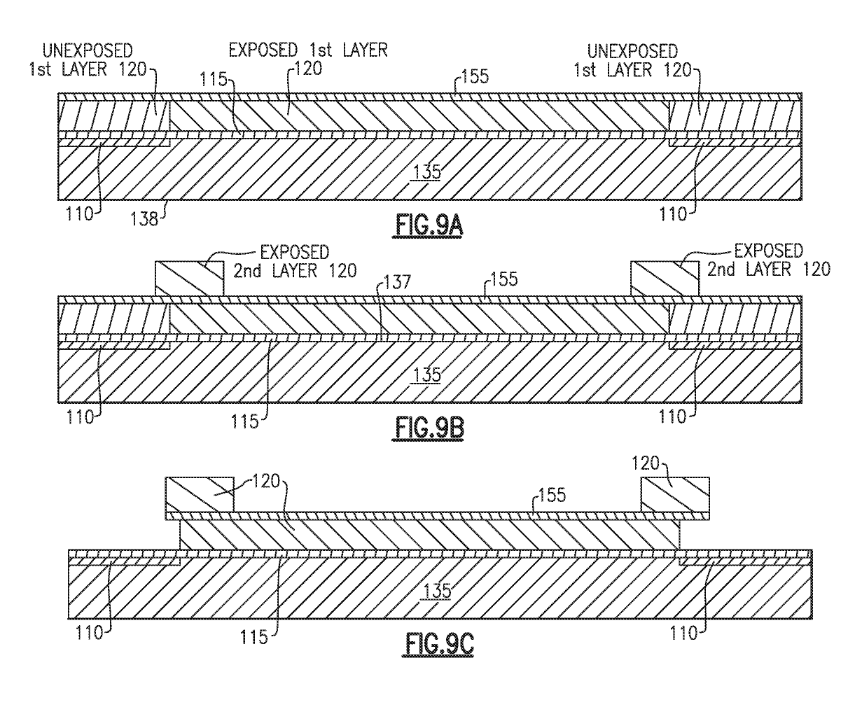

FIGS. 8A-8C illustrate an additional embodiment that highlights the flexibility in creating 3D structures of varying dimensions that may then be transferred to the device wafer using the methods disclosed herein. For instance, FIG. 8A illustrates a template wafer substrate 135 that includes two different deposition profiles for the optical masking material 110. The surface of the template wafer substrate 135 is configured to allow for an “overhang” feature (labeled as “a” in FIG. 8B) in the resulting layer of structure material 120 after it has been flood exposed and cured by applying light to the bottom surface 138. The optical masking material 110 near the feature labeled “b” in FIG. 8B has been deposited in such a manner so that no corresponding overhang is present in the resulting layer of structure material 120. FIG. 8C illustrates an embodiment where a layer of metal material 155 may be deposited onto the layer of structure material 120 corresponding to the region where the walls and lid surface of the resulting cavity reside once the structure material 120 and metal material 155 are transferred to a device wafer. The resulting cavity would thus have three sides comprising metal material 155, which in certain instances may not only provide a superior hermetic seal, but may also prevent or reduce issues related to outgassing, such as reduced device performance. In certain instances, the layer of metal material 155 may be deposited before the unreacted portions of the structure material 120 are removed (e.g., FIG. 7). The layer of metal material 155 may be deposited using any one of a number of different techniques. For instance, the layer of metal material 155 may be sputtered, and then portions of the metal material may be removed using a subtractive etch or lift off process.

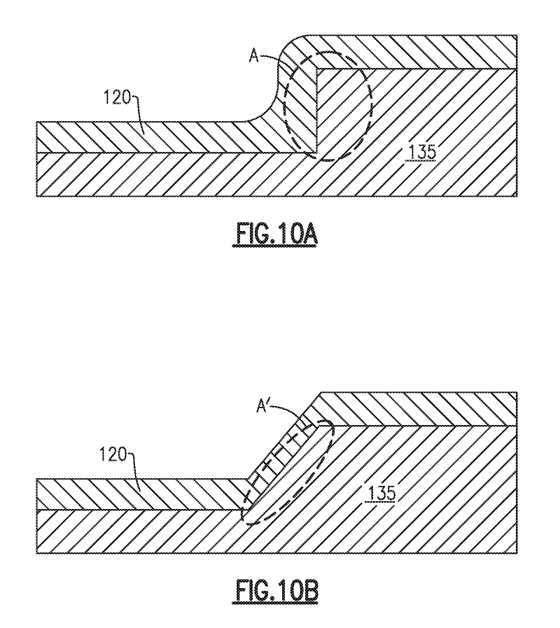

FIGS. 9A-9C illustrate another embodiment where different types of materials may be used in the 3D structures that are transferred to the device wafer. For instance, FIG. 9A includes a template wafer substrate 135 that includes a layer of temporary bonding material 115, and a first layer of structure material 120 that has been exposed to a source of light applied through the bottom surface 138 of the template wafer substrate 135, thereby creating unexposed and exposed portions of the first layer of structure material 120. Before the unexposed portions of the first layer of structure material 120 are developed or otherwise removed, a layer of metal material 155 is deposited on the planar surface created by the unexposed and exposed portions of the first layer of structure material 120. FIG. 9B illustrates where a second layer of structure material 120 has been deposited on top of the layer of metal material 155 and has been exposed to a source of light applied to the top surface 137 of the template wafer substrate 135, i.e., to the side of the template wafer substrate nearest where the layer of metal material 155 resides. Before the light is applied, a mask may be positioned over the second layer of structure material to create the raised features corresponding to the exposed second layer of structure material 120 shown in FIG. 9B. During this exposure step, the layer of metal material 155 functions as an optical masking material to the unexposed regions of the first layer of structure material 120. The layer of metal material 155 may also protect these regions from the removal process of the unreacted portions of the second layer of structure material 120. The structure shown in FIG. 9C is the result of additional removal steps that remove portions of the layer of metal material 155 and the unreacted portions of the first layer of structure material 120.

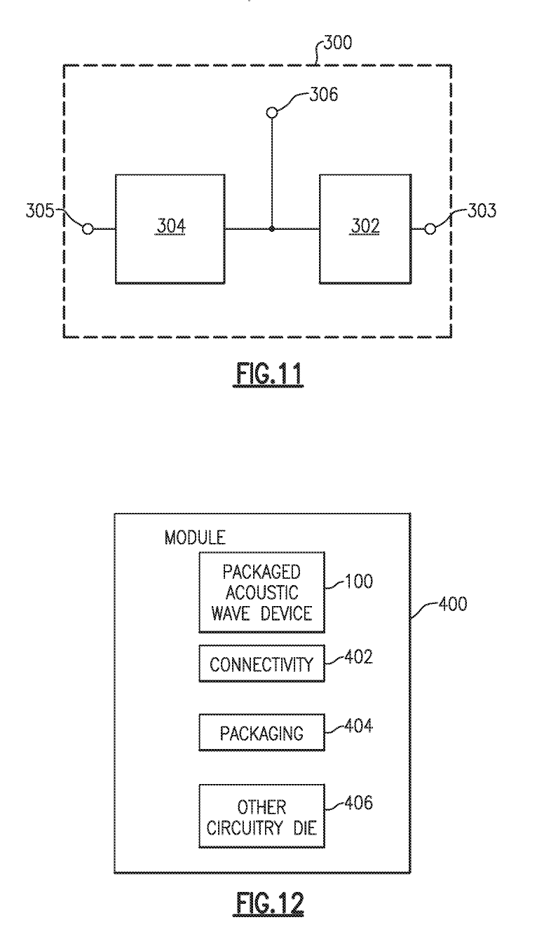

FIGS. 10A and 10B illustrate two different profiles that may be created for the layer of structure material according to the methods and systems disclosed herein. For example, FIG. 10A includes a template wafer substrate 135 that includes a step with a vertical drop, indicated at “A”. According to various aspects, one or more layers of structure material 120 may be deposited onto the template wafer substrate 135, and the resulting vertical “step” may be used to form wall or cavity structures in a resulting device. FIG. 10B illustrates a similar “step”, but includes a ramped drop, indicated at “A′” instead of a vertical drop. According to some embodiments, the vertical dimension (i.e., “depth”) of the vertical or ramped drop may be 5-10 microns and the layer of structure material 120 may have a thickness of about 5 microns, although other dimensions are within the scope of this disclosure. Although not explicitly shown in FIGS. 10A and 10B, a layer of temporary bonding material 120 may be deposited between the template wafer substrate 135 and the layer of structure material 120, as described herein.

The photolithographic processes discussed above with reference to forming 3D structured of the structure material 120 reference a type of photosensitive material that polymerizes or otherwise reacts with light to form a hardened layer. As will be appreciated by those of skill in the art, other types of photosensitive material may be used, such as those that actually photo-solubilize when exposed to light. Thus, exposed portions of this type of material are removed, and the unexposed portions actually form the 3D structures that are then transferred to the device wafer. Additional steps may be performed to render this type of structure material suitable for transfer.

According to some embodiments, the template wafer substrate 135 may be made from other materials besides optically transparent materials. In instances where a transparent material is not feasible for the template wafer substrate 135, an opaque substrate may be used and masking may be performed to remove one or more portions of the structure material 120. According to this embodiment, the layer of optical masking material on the template wafer substrate 135 may not be necessary, since a mask positioned over the surface of the structure material 120 may function to provide the same effect. The layer of structure material 120 may thus be exposed through “open” areas of the mask.

Processes 2A and 3B each depict one particular sequence of acts according to particular embodiments. As will be appreciated, some acts are optional and, as such, may be omitted in accord with one or more embodiments. Additionally, the order of acts can be altered, or other acts can be added, without departing from the scope of the embodiments described herein.

In accordance with one or more embodiments, the systems and method disclosed herein may be used to form packaged electronic devices. According to some embodiments, the packaged electronic device may be an acoustic wave device, such as a SAW filter. It will be appreciated by those skilled in the art, given the benefit of this disclosure, that components or devices, such as an acoustic wave filter, an antenna duplexer, a module, or a communications device, for example, may be configured to use embodiments of the 3D structures disclosed herein, and that such components or devices may have enhanced or improved features through the benefits provided by the 3D structures.

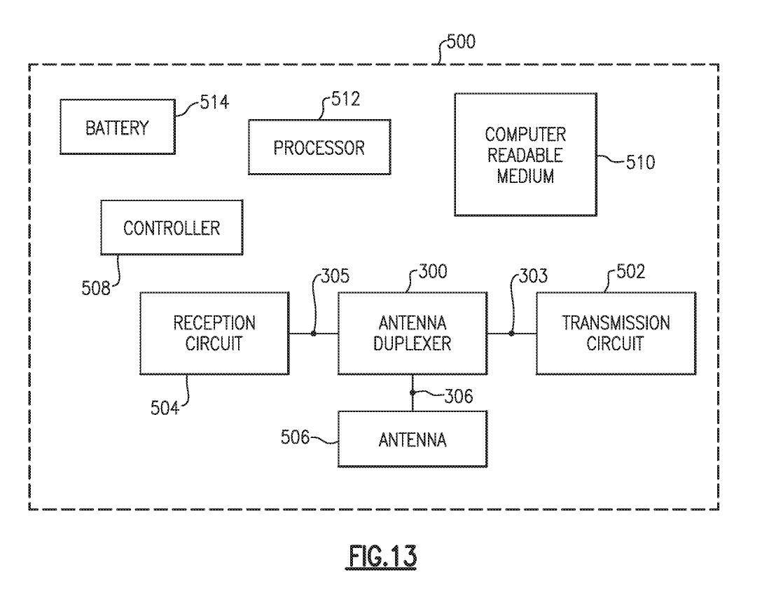

According to one embodiment, a packaged electronic device including an acoustic wave device may be used to provide an antenna duplexer having improved characteristics. FIG. 11 illustrates a block diagram of one example of an antenna duplexer which can incorporate embodiments of the packaged electronic device using the 3D structure disclosed herein. The antenna duplexer 300 includes a transmission filter 302 and a reception filter 304 that are connected to a shared antenna terminal 306. The transmission filter 302 includes a transmit terminal 303 for connecting the transmission filter to transmitter circuitry (not shown), and the reception filter includes a reception terminal 305 for connecting the reception filter to receiver circuitry (not shown). Either or both of the transmission filter 302 and the reception filter 304 can include one or more of the packaged electronic devices, such as an acoustic wave device, as disclosed herein. By configuring the antenna duplexer 300 to use the packaged acoustic wave devices, an antenna duplexer having improved characteristics and enhanced performance (resulting from the improved characteristics of the packaged acoustic wave devices discussed above such as the enhanced sealing characteristics can be realized. Furthermore, the risk of contaminating the device wafer that carries the packaged acoustic wave devices may be reduced, since processing of at least some of the structure is performed on a separate wafer and then transferred.

Further, embodiments of the packaged acoustic wave devices may be incorporated, optionally as part of the antenna duplexer 300, into a module that may ultimately be used in a device, such as a wireless communications device, for example, so as to provide a module having enhanced performance. FIG. 12 is a block diagram illustrating one example of a module 400 including an embodiment of a packaged acoustic wave device 100. The module 400 further includes connectivity 402 to provide signal interconnections, packaging 404, such as for example, a package substrate, for packaging of the circuitry, and other circuitry die 406, such as, for example amplifiers, pre-filters, modulators, demodulators, down converters, and the like, as would be known to one of skill in the art of semiconductor fabrication in view of the disclosure herein. In certain embodiments, the packaged acoustic wave device 100 in module 400 may be replaced with the antenna duplexer 300, so as to provide an RF module, for example.

Furthermore, configuring an acoustic wave filter and/or antenna duplexer to use embodiments of the packaged acoustic wave device can achieve the effect of realizing a communication device having enhanced performance using the same. FIG. 13 is a schematic block diagram of one example of a communication device 500 (e.g., a wireless or mobile device) that can include the antenna duplexer 300 incorporating one or more packaged acoustic wave devices, as discussed above. The communication device 500 can represent a multi-band and/or multi-mode device such as a multi-band/multi-mode mobile phone, for example. In certain embodiments, the communication device 500 can include the antenna duplexer 300, a transmission circuit 502 connected to the antenna duplexer via the transmit terminal 303, a reception or receive circuit 504 connected to the antenna duplexer 300 via the reception terminal 305, and an antenna 506 connected to the antenna duplexer via the antenna terminal 306. The transmission circuit 502 and reception circuit 504 may be part of a transceiver that can generate RF signals for transmission via the antenna 506 and can receive incoming RF signals from the antenna 506. The communication device 500 can further include a controller 508, a computer readable medium 510, a processor 512, and a battery 514.

It will be understood that various functionalities associated with the transmission and receiving of RF signals can be achieved by one or more components that are represented in FIG. 13 as the transmission circuit 502 and the reception circuit 504. For example, a single component can be configured to provide both transmitting and receiving functionalities. In another example, transmitting and receiving functionalities can be provided by separate components.

Similarly, it will be understood that various antenna functionalities associated with the transmission and receiving of RF signals can be achieved by one or more components that are collectively represented in FIG. 13 as the antenna 506. For example, a single antenna can be configured to provide both transmitting and receiving functionalities. In another example, transmitting and receiving functionalities can be provided by separate antennas. In yet another example in which the communication device is a multi-band device, different bands associated with the communication device 500 can be provided with different antennas.

To facilitate switching between receive and transmit paths, the antenna duplexer 300 can be configured to electrically connect the antenna 506 to a selected transmit or receive path. Thus, the antenna duplexer 300 can provide a number of switching functionalities associated with an operation of the communication device 500. In addition, as discussed above, the antenna duplexer 300 may include the transmission filter 302 and reception filter 304, which are configured to provide filtering of the RF signals. As discussed above, either or both of the transmission filter 302 and reception filter 304 can include embodiments of the packaged acoustic wave device, and thereby provide enhanced features and/or performance through the benefits of the ability to downsize and improved connection reliability achieved using embodiments of the packaged acoustic wave device. In certain examples, the antenna duplexer 300 in the communication device 500 can be replaced with a module 400, which includes the antenna duplexer, as discussed above.

As shown in FIG. 13, in certain embodiments, a controller 508 can be provided for controlling various functionalities associated with operations of the antenna duplexer 300 and/or other operating component(s). In certain embodiments, a processor 512 can be configured to facilitate implementation of various processes for operation of the communication device 500. The processes performed by the processor 512 may be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create a mechanism for operating the communication device 500. In certain embodiments, these computer program instructions may also be stored in the computer-readable medium 510. The battery 514 can be any suitable battery for use in the communication device 500, including, for example, a lithium-ion battery.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while acts of the disclosed processes are presented in a given order, alternative embodiments may perform routines having acts performed in a different order, and some processes or acts may be deleted, moved, added, subdivided, combined, and/or modified. Each of these processes or acts may be implemented in a variety of different ways. Also, while processes or acts are at times shown as being performed in series, these processes or acts may instead be performed in parallel, or may be performed at different times.

The teachings of the invention provided herein can be applied to other systems, not necessarily the system described above. The elements and acts of the various embodiments described above can be combined to provide further embodiments.

Having thus described several aspects of at least one example, it is to be appreciated that various alterations, modifications, and improvements will readily occur to those skilled in the art. For instance, examples disclosed herein may also be used in other contexts. Such alterations, modifications, and improvements are intended to be part of this disclosure, and are intended to be within the scope of the examples discussed herein. Accordingly, the foregoing description and drawings are by way of example only.

What is claimed is:

1. A method of forming a packaged electronic device, comprising:
treating a surface of a first substrate to create a first surface having a low bond strength, at least a portion of the first surface defined by at least one three-dimensional structure and a layer of optical masking material;
depositing a layer of structure material onto the at least a portion of the first surface;
bonding a second substrate to at least a portion of the layer of structure material; and
separating the first substrate from the second substrate along the first surface.

2. The method of claim 1 wherein the second substrate is bonded to a first portion of the layer of structure material and the method further comprises removing a second portion of the structure material prior to bonding the second substrate to the first portion.

3. The method of claim 2 wherein removing the second portion includes exposing the second portion of the structure material to a source of light.

4. The method of claim 3 wherein exposing the second portion of the structure material includes directing the source of light through a second surface of the first substrate, the second surface opposing the first surface.

5. The method of claim 4 wherein the layer of optical masking material blocks the light from the first portion of the structure material.

6. The method of claim 1 wherein treating the surface of the first substrate includes depositing a layer of temporary bonding material onto the first surface.

7. The method of claim 1 wherein the layer of structure material is deposited on at least one recessed portion and at least one raised portion of the three-dimensional structure such that the layer of structure material that is deposited on the at least one recessed portion and the at least one raised portion defines at least one cavity when the second substrate is bonded to the structure material.

8. The method of claim 7 wherein the second substrate includes at least one electronic device disposed on a portion of a surface of the second substrate that is within the at least one cavity, the method further comprising:
forming at least one bonding structure on at least a portion of the layer of structure material; and
mounting the at least one electronic device in an electronic device module.

9. A reusable template wafer, comprising:
a substrate having a first surface defined by a three-dimensional topography; and
a layer of optical masking material disposed on at least a portion of the first surface.

10. The reusable template wafer of claim 9 wherein the layer of optical masking material is disposed in at least a portion of at least one recessed portion of the three-dimensional topography.

11. The reusable template wafer of claim 10 wherein the at least one recessed portion includes a first portion having a first depth and a second portion having a second depth that is different than the first depth.

12. The reusable template wafer of claim 9 wherein at least a portion of the first surface has a low bond strength that is created by a layer of temporary bonding material disposed on the first surface and the layer of optical masking material.

13. The reusable template wafer of claim 12 wherein the temporary bonding material is one of a polyvinyl alcohol (PVA) and a halocarbon.

14. The reusable template wafer of claim 9 wherein the substrate is constructed from a material that is UV transparent.

15. The reusable template wafer of claim 12 further comprising a layer of structure material disposed on at least a portion of the first surface.

16. The reusable template wafer of claim 15 wherein the layer of structure material is a photosensitive polymer.

17. The reusable template wafer of claim 16 wherein the photosensitive polymer is a polyimide.

18. The reusable template wafer of claim 15 wherein the layer of structure material has a thickness in a range of from about three to about five microns.

19. The reusable template wafer of claim 15 further comprising a device wafer substrate attached to at least a portion of the layer of structure material, a portion of the layer of structure material not attached to the device wafer substrate defining a cavity formed adjacent a portion of the device wafer substrate.

20. The reusable template wafer of claim 19 wherein the device wafer substrate includes an acoustic wave filter disposed on a portion of a surface of the device wafer substrate that is within the cavity.
